(19) United States
(12) Patent Application Publication
(10) Pub. No.: US 2023/0413697 A1
(43) Pub. Date: Dec. 21, 2023

(54) RESISTIVE RANDOM-ACCESS MEMORY DEVICES WITH COMPOUND NON-REACTIVE ELECTRODES

(71) Applicant: TetraMem Inc., Fremont, CA (US)

(72) Inventors: Minxian Zhang, Amherst, MA (US); Mingche Wu, San Jose, CA (US); Ning Ge, Danville, CA (US)

(73) Assignee: TetraMem Inc., Fremont, CA (US)

(21) Appl. No.: 18/163,272

(22) Filed: Feb. 1, 2023

Related U.S. Application Data
(63) Continuation-in-part of application No. 17/843,347, filed on Jun. 17, 2022.

(51) Int. Cl. H10N 70/00; H10B 63/00

(52) U.S. Cl. CPC H10N 70/883; H10B 63/30; H10N 70/841; H10N 70/021

(57) ABSTRACT

The present disclosure relates to resistive random-access memory (RRAM) devices. In some embodiments, an RRAM device includes: a first electrode; a second electrode comprising a first conductive material; and a switching oxide layer positioned between the first electrode and the second electrode. The switching oxide layer includes at least one transition metal oxide. The first electrode includes a metal nitride layer containing a metal nitride and a metal layer fabricated on the metal nitride layer. The metal layer includes a metal that is not reactive to the at least one transition metal oxide. In some embodiments, the metal nitride in the first electrode includes titanium nitride and/or tantalum nitride. The metal layer includes a layer of a noble metal, such as platinum, palladium, iridium, or ruthenium, etc.

### CROSS-REFERENCE TO RELATED APPLICATIONS

The present application is a continuation-in-part of U.S. patent application Ser. No. 17/843,347, entitled “Resistive Random-Access Memory Devices with Metal-Nitride Compound Electrodes,” filed on Jun. 17, 2022, which is incorporated by reference in its entirety.

### TECHNICAL FIELD

The implementations of the disclosure relate generally to resistive random-access memory (RRAM) devices and, more specifically, to RRAM devices with compound non-reactive electrodes.

### BACKGROUND

A resistive random-access memory (RRAM) device is a two-terminal passive device with tunable and non-volatile resistance. The resistance of the RRAM device may be electrically switched between a high-resistance state (HRS) and a low-resistance state (LRS) by applying suitable programming signals to the RRAM device. RRAM devices may be used to form crossbar arrays that may be used to implement in-memory computing applications, non-volatile solid-state memory, image processing applications, neural networks, etc.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, a resistive random-access memory (RRAM) device includes: a first electrode; a second electrode including a conductive material; and a switching oxide layer positioned between the first electrode and the second electrode. The first electrode includes: a metal nitride layer including a metal nitride; and a metal layer fabricated on the metal nitride layer. The switching oxide layer includes at least one transition metal oxide. In some embodiments, the metal layer includes a metal that is not reactive to the at least one transition metal oxide.

In some embodiments, the metal nitride includes at least one of titanium nitride or tantalum nitride.

In some embodiments, the metal that is not reactive to the at least one transition metal oxide includes at least one of platinum, palladium, iridium, or ruthenium.

In some embodiments, the metal layer is thinner than the metal nitride layer.

In some embodiments, a thickness of the metal layer is between 3 nm and 10 nm.

In some embodiments, a thickness of the metal nitride layer is between 20 nm and 50 nm.

In some embodiments, the at least one transition metal oxide includes at least one of HfOₓ or TaO_{y}, wherein x≤2.0, and wherein y≤2.5.

In some embodiments, the conductive material in the second electrode includes tantalum.

In some embodiments, the RRAM device further includes an interface layer positioned between the switching oxide layer and the second electrode. In some embodiments, the interface layer includes aluminum oxide.

In some embodiments, the RRAM device further includes an adhesive layer including at least one of titanium or tantalum, wherein the metal nitride layer is fabricated on the adhesive layer.

According to one or more aspects of the present disclosure, a method for fabricating a resistive random-access memory (RRAM) device includes: fabricating a first electrode; fabricating a switching oxide layer on the first electrode; and fabricating, on the switching oxide layer, a second electrode including a conductive material. The switching oxide layer includes at least one transition metal oxide. The first electrode includes: a metal nitride layer including a metal nitride; and a metal layer fabricated on the metal nitride layer. In some embodiments, the metal layer includes a metal that is not reactive to the at least one transition metal oxide.

In some embodiments, the metal nitride includes at least one of titanium nitride or tantalum nitride.

In some embodiments, the metal that is not reactive to the at least one transition metal oxide includes at least one of platinum, palladium, iridium, or ruthenium.

In some embodiments, the metal layer is thinner than the metal nitride layer.

In some embodiments, a thickness of the metal layer is between 3 nm and 10 nm.

In some embodiments, a thickness of the metal nitride layer is between 20 nm and 50 nm.

In some embodiments, the at least one transition metal oxide includes at least one of HfOₓ or TaO_{y}, wherein x≤2.0, and wherein y≤2.5.

In some embodiments, the method further includes fabricating an interface layer on the switching oxide layer, wherein the interface layer is positioned between the switching oxide layer and the second electrode, and wherein the interface layer includes aluminum oxide.

In some embodiments, the method further includes fabricating an adhesive layer including at least one of titanium or tantalum, wherein the metal nitride layer is fabricated on the adhesive layer.

According to one or more aspects of the present disclosure, a method for fabricating a non-reactive electrode includes: fabricating an adhesive layer including at least one of titanium or tantalum; fabricating, on the adhesive layer, a metal nitride layer including at least one metal nitride, wherein the metal nitride includes at least one of titanium nitride or tantalum nitride; fabricating, on the metal nitride layer, a metal layer includes a noble metal; and selectively removing one or more portions of the adhesive layer, the metal nitride layer, and the metal layer to fabricate the non-reactive electrode.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIG. 1 is a schematic diagram illustrating an example of a crossbar circuit in accordance with some implementations of the disclosure.

FIG. 2 is a schematic diagram illustrating an example of a cross-point device in accordance with some implementations of the present disclosure.

FIG. 3A illustrates a cross-sectional view of an example RRAM device in accordance with some embodiments of the present disclosure.

FIGS. 3B and 3C illustrate cross-sectional views of the RRAM device of FIG. 3A in a low-resistance state and a high-resistance state, respectively.

FIG. 4 illustrates a cross-sectional view of an example 400 of a compound non-reactive electrode in accordance with another implementation of the present disclosure.

FIGS. 5, 6, and 7 illustrate cross-sectional views of example RRAM devices in accordance with some embodiments of the present disclosure.

FIGS. 8A, 8B, 8C, 8D, 8E, and 8F are schematic diagrams illustrating cross-sectional views of structures for fabricating non-reactive electrodes of RRAM devices in accordance with some embodiments of the present disclosure.

FIG. 9A shows I-V (current-voltage) characteristics of an RRAM device in accordance with some embodiments of the present disclosure.

FIG. 9B is an I-V curve showing the analog behavior of an RRAM device in accordance with some embodiments of the present disclosure.

FIG. 9C is a diagram illustrating device read current characteristics of an example RRAM device over time in accordance with some embodiments of the present disclosure.

FIG. 10 is a flow diagram illustrating an example method for fabricating an RRAM device according to some embodiments of the disclosure.

FIG. 11 is a flow diagram illustrating an example of a method for fabricating a non-reactive electrode according to some embodiments of the disclosure.

### DETAILED DESCRIPTION

Aspects of the disclosure provide resistive random-access memory (RRAM) devices and methods for fabricating the RRAM devices. An RRAM device is a two-terminal passive device with tunable resistance. The RRAM device may include a first electrode, a second electrode, and a switching oxide layer positioned between the first electrode and the second electrode. In some embodiments, the first electrode and the second electrode may be a bottom electrode and a top electrode of the RRAM device, respectively. In some embodiments, the first electrode and the second electrode may be a top electrode and a bottom electrode of the RRAM device, respectively. The first electrode may include a non-reactive metal, such as platinum (Pt), palladium (Pd), ruthenium (Ru), etc. The second electrode may include a reactive metal, such as tantalum (Ta). The electrode including the non-reactive metal is also referred to herein as the “non-reactive electrode.” The electrode including the reactive metal is also referred to herein as the “reactive electrode.” The switching oxide layer may include a transition metal oxide, such as hafnium oxide (HfOₓ) or tantalum oxide (TaOₓ). The RRAM device may be in an initial state or virgin state and may have an initial high resistance before it is subject to a suitable electrical stimulation (e.g., a voltage or current signal applied to the RRAM device). The RRAM device may be tuned to a lower resistance state from the virgin state via a forming process or from a high-resistance state (HRS) to a lower resistance state (LRS) via a setting process. The forming process may refer to programming a device starting from the virgin state. The setting process may refer to programming a device starting from the high resistance state (HRS). After the reactive metal electrode is deposited on the switching oxide, the reactive metal can absorb oxygen from the switching oxide layer and create oxygen vacancies in the switching oxide layer, and oxygen ions can migrate in the switching oxide through a vacancy mechanism. During a forming process, a suitable programming signal (e.g., a voltage or current signal) may be applied to the RRAM device, which may cause a drift of oxygen ions to migrate from the switching oxide to the reactive electrode. As a result, a conductive channel or filament may form through the switching oxide layer (e.g., from the reactive electrode to the non-reactive electrode). The RRAM device may then be reset to a high-resistance state by applying a reset signal (e.g., a voltage signal, a current signal) to the RRAM device. The application of the reset signal to the RRAM device may cause oxygen to migrate back to the switching oxide layer and may thus interrupt the conductive filament. The RRAM device may be electrically switched between a high-resistance state and a low-resistance state by applying suitable programming signals (e.g., voltage signals, current signals, etc.) to the RRAM device. In a crossbar array circuit, the programming signals may be provided to the designated RRAM device via a selector, such as a transistor or a diode.

An RRAM device with platinum (Pt) in its non-reactive electrode may provide RRAM high performance such as reliability, endurance, multi-levels, retention, etc. In an RRAM including a bottom electrode of Pt, a switching oxide layer including TaOₓ, and a top electrode including Ta (also referred to as a “Pt/TaOₓ/Ta system”), a Ta filament in the TaOₓ showed excellent behaviors such as linearity, analog, retention, and endurance for in-memory computing (IMC) applications. In a Pt/HfOₓ/Ta system, Ta can migrate into the HfOₓ to form a Ta-rich filament in the HfOₓ, and showed excellent behaviors such as linearity, analog, retention, and endurance for IMC applications. However, platinum's material and processing costs may be high, and major fabrication plants may not be ready yet to incorporate platinum in their processes.

According to some embodiments of the present disclosure, a compound non-reactive electrode of an RRAM device may include a metal nitride layer and a metal layer. The metal nitride layer may include one or more metal nitrides, such as TiN, TaN, etc. The metal layer may include a non-reactive metal, such as Pt, Pd, Ru, Ir, etc. The metal layer may be substantially thinner than the metal nitride layer. For example, the metal nitride layer may be between about 20 nm and 25 nm, and the metal layer may be between about 3 nm and about 8 nm in some embodiments.

Both TiN and TaN are electrically conductive materials and are also compatible with CMOS (complementary metal-oxide semiconductor) processes, ready for volume production, and have much lower production costs than Pt. RRAM devices with TiN or TaN in their non-reactive electrodes may present certain characteristics desirable for IMC applications, such as multi-level switching resistance and/or analog behavior. Compared to RRAM devices with non-reactive electrodes containing TiN or TaN alone, RRAM devices with non-reactive electrodes containing Pt may have better performance but may be more costly. By incorporating a metal nitride layer and a metal layer (e.g., a layer of Pt, Pd, Ru, Ir, etc.) that is substantially thinner than the metal nitride layer, the mechanisms for fabricating compound non-reactive electrode described herein provide a cost-effective solution for fabricating RRAM devices with desirable switching and analog resistance behaviors.

Compared with conventional RRAM devices using Pt-based non-reactive electrodes, RRAM devices using the compound non-reactive electrodes described herein have lower material and processing costs, are ready for CMOS processes, and are ready for volume production. The RRAM devices disclosed herein present suitable performance and abilities on multiple-switching and analog behavior.

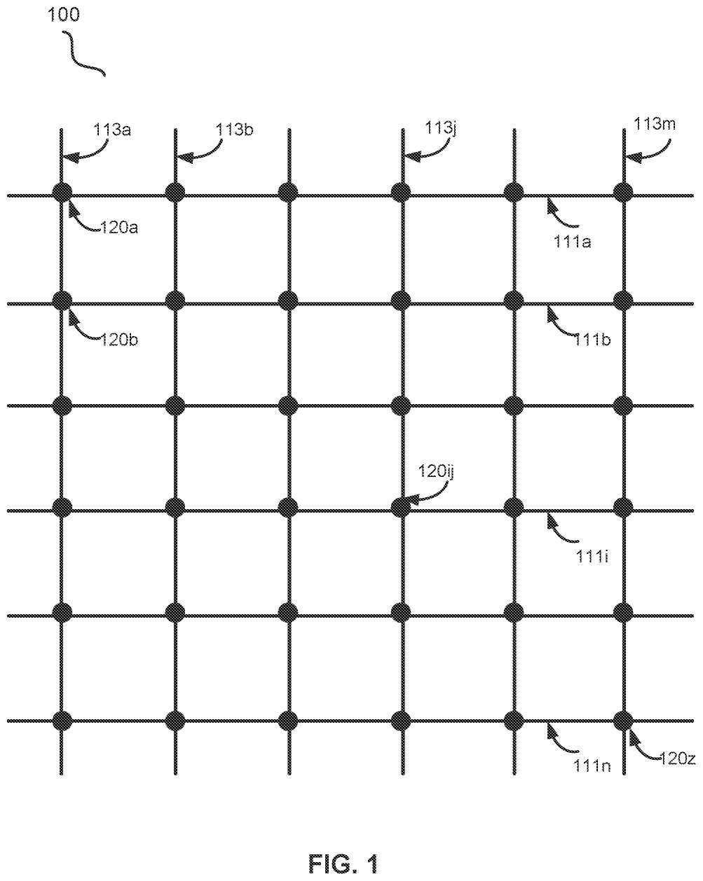

FIG. 1 is a schematic diagram illustrating an example 100 of a crossbar circuit in accordance some embodiments of the present disclosure. As shown, crossbar circuit 100 may include a plurality of interconnecting electrically conductive wires, such as one or more row wires 111a, 111b, . . . , 111i, . . . , 111n, and column wires 113a, 113b, . . . , 113j, . . . , 113m for an n-row by m-column crossbar array. The crossbar circuit 100 may further include cross-point devices 120a, 120b, . . . , 120z, etc. Each of the cross-point devices may connect a row wire and a column wire. For example, the cross-point device 120ij may connect the row wire 111i and the column wire 113j. In some embodiments, crossbar circuit 100 may further include digital to analog converters (DAC, not shown), analog to digital converters (ADC, not shown), switches (not shown), and/or any other suitable circuit components for implementing a crossbar-based apparatus. The number of the column wires 113a-m and the number of the row wires 111a-n may or may not be the same.

Row wires 111 may include a first row wire 111a, a second row wire 111b, . . . , 111i, . . . , and an n-th row wire 111n. Each of row wires 111a, . . . , 111n may be and/or include any suitable electrically conductive material. In some embodiments, each row wire 111a-n may be a metal wire.

Column wires 113 may include a first column wire 113a, a second column wire 113b, . . . , and an m-th column wire 113m. Each of column wires 113a-m may be and/or include any suitable electrically conductive material. In some embodiments, each column wire 113a-m may be a metal wire.

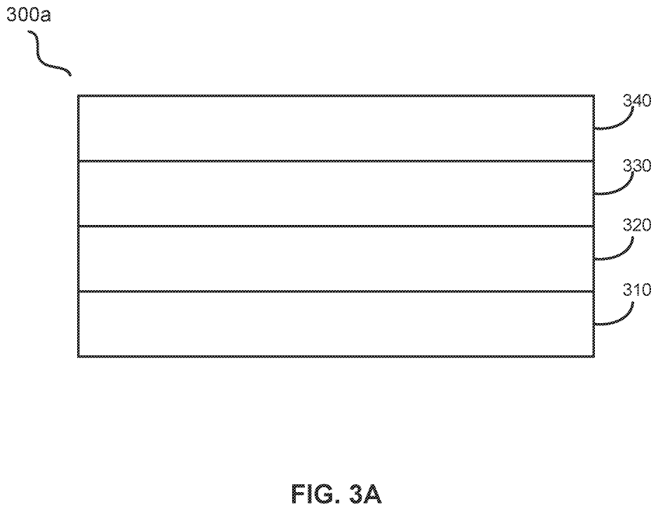

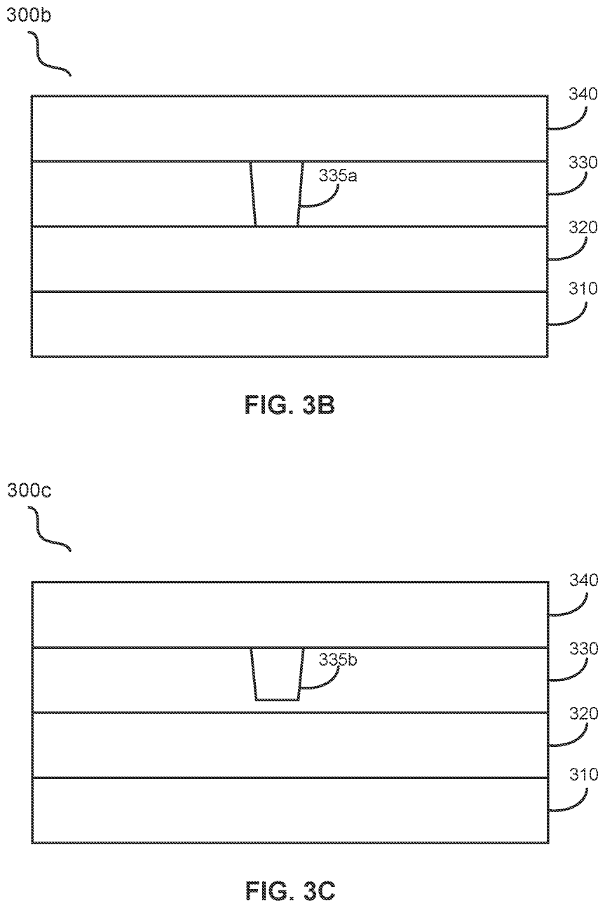

Each cross-point device 120 may be and/or include any suitable device with tunable resistance, such as a memristor, PCM (phase change memory) devices, floating gates, spintronic devices, resistive random-access memory (RRAM), static random-access memory (SRAM), etc. In some embodiments, one or more of cross-point devices 120 may include an RRAM device as described in connection with FIGS. 3A-9C.

Crossbar circuit 100 may perform parallel weighted voltage multiplication and current summation. For example, an input voltage signal may be applied to one or more rows of crossbar circuit 100 (e.g., one or more selected rows). The input signal may flow through the cross-point devices of the rows of the crossbar circuit 100. The conductance of the cross-point device may be tuned to a specific value (also referred to as a “weight”). By Ohm's law, the input voltage multiplies the cross-point conductance and generates a current from the cross-point device. By Kirchhoff's law, the summation of the current passing the devices on each column generates the current as the output signal, which may be read from the columns (e.g., outputs of the ADCs). According to Ohm's law and Kirchhoff's current law, the input-output relationship of the crossbar array can be represented as I=VG, wherein I represents the output signal matrix as current; V represents the input signal matrix as voltage; and G represents the conductance matrix of the cross-point devices. As such, the input signal is weighted at each of the cross-point devices by its conductance according to Ohm's law. The weighted current is outputted via each column wire and may be accumulated according to Kirchhoff's current law. This may enable in-memory computing (IMC) via parallel multiplications and summations performed in the crossbar arrays.

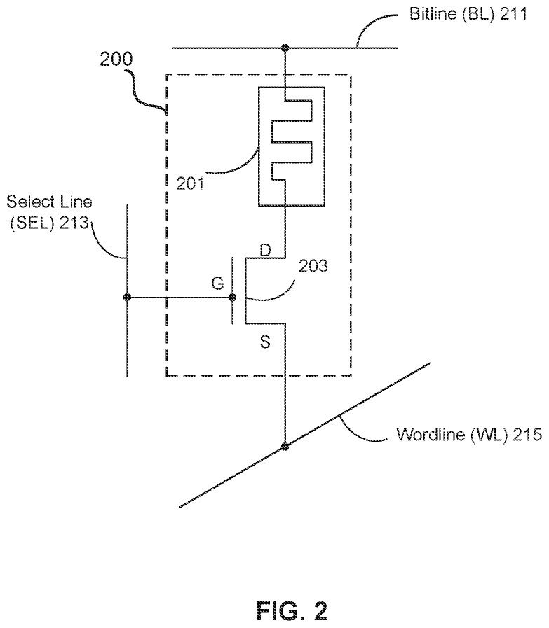

FIG. 2 is a schematic diagram illustrating an example 200 of a cross-point device in accordance some embodiments of the present disclosure. As shown, cross-point device 200 may connect a bitline (BL) 211, a select line (SEL) 213, and a wordline (WL) 215. The bitline 211 and the wordline 215 may be a column wire and a row wire as described in connection with FIG. 1, respectively.

Cross-point device 200 may include an RRAM device 201 and a transistor 203. A transistor is a three-terminal device, which may be marked as gate (G), source (S), and drain (D), respectively. The transistor 203 may be serially connected to RRAM device 201. As shown in FIG. 2, the first electrode of the RRAM device 201 may be connected to the drain of transistor 203. The second electrode of the RRAM device 201 may be connected to the bitline 211. The source of the transistor 203 may be connected to the wordline 215. The gate of the transistor 203 may be connected to the select line 213. RRAM device 201 may include one or more RRAM devices as described in connection with FIGS. 3A-9C below. Cross-point device 200 may also be referred to as a one-transistor-one-resistor (1T1R) configuration. The transistor 203 may perform as a selector as well as a current controller, which may set the current compliance, to the RRAM device 201 during programming. The gate voltage on transistor 203 can set current compliances to cross-point device 200 during programming and can thus control the conductance and analog behavior of cross-point device 200. For example, when cross-point device 200 is set from a high-resistance state to a low-resistance state, a set signal (e.g., a voltage signal, a current signal) may be provided via the bitline (BL) 211. Another voltage, also referred as a select voltage or gate voltage, may be applied via the select line (SEL) 213 to the transistor gate to open the gate and set the current compliance, while the wordline (WL) 215 may be set to ground. When cross-point device 200 is reset from the low-resistance state to the high-resistance state, a gate voltage may be applied to the gate of the transistor 203 via the select line 213 to open the transistor gate. Meanwhile, a reset signal may be sent to the RRAM device 201 via the wordline 215, while the bitline 211 may be set to ground.

FIGS. 3A, 3B, and 3C illustrate cross-sectional views of example RRAM devices 300a, 300b, and 300c in accordance with some embodiments of the present disclosure. RRAM devices 300b, and 300c may correspond to a low-resistance state and a high-resistance state of RRAM device 300a, respectively.

As shown in FIG. 3A, RRAM device 300a may include a substrate 310, a first electrode 320 fabricated on substrate 310, a switching oxide layer 330, and a second electrode 340. Switching oxide layer 330 is fabricated between first electrode 320 and second electrode 340. Substrate 310 may include one or more layers of any suitable material that may serve as a substrate for an RRAM device, such as silicon (Si), silicon dioxide (SiO₂), silicon nitride (Si₃N₄), aluminum oxide (Al₂O₃), aluminum nitride (AlN), etc. In some embodiments, substrate 310 may include diodes, transistors, interconnects, integrated circuits, etc. In some embodiments, the substrate may include a driving circuit including one or more electrical circuits (e.g., an array of electrical circuits) that may be individually controllable. In some embodiments, the driving circuit may include one or more complementary metal-oxide-semiconductor (CMOS) drivers.

First electrode 320 may include a metal nitride that is electronically conductive and non-reactive to the switching oxide layer to be fabricated. The metal nitride may have a suitable chemical stability so that it does not react with oxygen during RRAM switching. The metal nitride may include, for example, titanium nitride (TiN), tantalum nitride (TaN), etc. First electrode 320 may further include a non-reactive metal that is electronically conductive and does not react with oxygen during RRAM switching, such as such as platinum (Pt), palladium (Pd), iridium (Ir), ruthenium (Ru), etc. RRAM devices with the metal nitride and the non-reactive metal in their non-reactive electrodes have multi-level resistance and the analog behavior desirable for IMC applications.

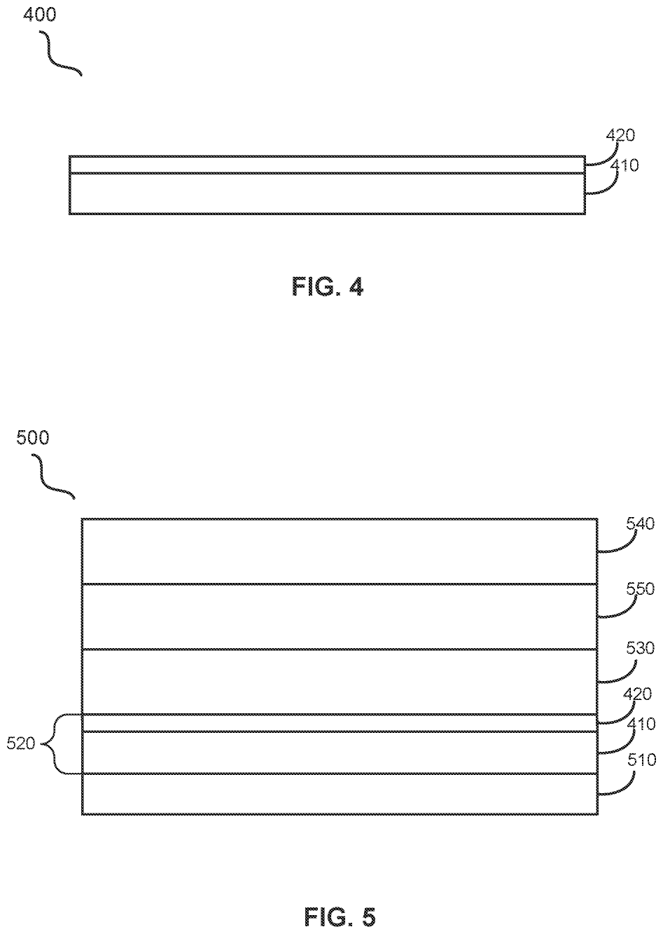

In some embodiments, first electrode 320 may be and/or include a compound bottom electrode as described in connection with FIG. 4. For example, first electrode 320 may include a metal nitride layer containing one or more metal nitrides (e.g., TiN, TaN, etc.). First electrode 320 may further include a metal layer containing one or more noble metals (e.g., Pt, Pb, Ir, Ru, etc.) fabricated on the metal nitride layer. The metal layer is thinner than the metal nitride layer in some embodiments.

In some embodiments, a layer of Ta and/or Ti (not shown in FIG. 3C) may be fabricated between first electrode and substrate 310 to enhance the adhesion between substrate 310 and the components of the RRAM device 300a.

Switching oxide layer 330 may include one or more transition metal oxides, such as TaOₓ, HfOₓ, TiOₓ, NbOₓ, ZrOₓ, etc., in binary oxides, ternary oxides, and high order oxides. In some embodiments, the chemical stability of the non-reactive material in first electrode 320 may be higher than that of the transition metal oxide(s) in switching oxide layer 330. In some embodiments, the transition metal oxide(s) include at least one of HfOₓ or TaOₓ, wherein x may be used to indicate the oxide being oxygen deficient compared to its full (or terminal) oxide and the value of x may be varied from the oxygen to metal atomic ratio in the stoichiometry of its full oxide, such as x≤2.0 for HfOₓ (where HfO₂ being the full oxide), and x≤2.5 for TaOₓ (where Ta₂O₅ being the full oxide).

Second electrode 340 may include any suitable metallic material that are electronically conductive and reactive to the switching oxide. For example, the metallic material in second electrode 340 may include Ta, Hf, Ti, TiN, TaN, etc. Second electrode 340 may be reactive to the switching oxide and may have suitable oxygen solubility to adsorb some oxygen from the switching oxide layer 330 and create oxygen vacancies in the switching oxide layer 330. In other words, the reactive metallic material(s) in second electrode 340 may have suitable oxygen solubility and/or oxygen mobility. In some embodiments, second electrode 340 not only may be able to create oxygen vacancies in switching oxide layer 330 (e.g., by scavenging oxygen), but also may function as oxygen reservoir or source to the switching oxide layer 330 during cell programming.

RRAM device 300a may have an initial resistance (also referred to herein as the “virgin resistance”) after it is fabricated. The initial resistance of RRAM device 300a may be changed and RRAM device 300a may be switched to a state of a lower resistance via a forming process. For example, a suitable voltage or current may be applied to RRAM device 300a. The application of the voltage to RRAM device 300a may induce the metallic material(s) in the second electrode to absorb oxygen from the switching oxide layer 330 and create oxygen vacancies in the switching oxide layer 330. As a result, a conductive channel (e.g., a filament) which is oxygen vacancy rich may form in the switching oxide layer 330. For example, as illustrated in FIG. 3B, a conductive channel 335a may be formed in the switching oxide layer 330. As shown, conductive channel 335a may be formed from the second electrode 340 to the first electrode 320 across the switching oxide layer 330. RRAM device 300b may be reset to a high-resistance state. For example, a reset signal (e.g., a voltage signal or a current signal) may be applied to RRAM device 300b during a reset process. In some embodiments, the set signal and the reset signal may have opposite polarity, i.e., a positive signal and a negative signal, respectively. The application of the reset signal may cause oxygen to drift back to the switching oxide layer 330 and recombine with one or more of the oxygen vacancies. For example, an interrupted conductive channel 335b as shown in FIG. 3C may be formed in the switching oxide layer 330 during the reset process. As shown, the conductive channel may be interrupted with an oxide gap between the interrupted conductive channel 335b and the first electrode 320. The lateral dimension of the interrupted conductive channel 335b may be smaller than that of the conductive channel 335a. In some embodiments, the interrupted conductive channel 335b does not continuously connect the first electrode 320 and the second electrode 340. RRAM device 300a-c may be electrically switched between the high-resistance state and the low-resistance state by applying suitable programming signals (e.g., voltage signals, current signals, etc.) to the RRAM device.

In one implementation, second electrode 340 may include one or more alloys. Each of the alloys may contain two or more metallic elements. Each of the alloys may include a binary alloy (e.g., an alloy containing two metallic elements), a ternary alloy (e.g., an alloy containing three metallic elements), a quaternary alloy (e.g., an alloy containing four metallic elements), a quinary alloy (e.g., an alloy containing five metallic elements), a senary alloy (e.g., an alloy containing six metallic elements), and/or a high order alloy (e.g., an alloy containing more than six metallic elements). In some embodiments, the second electrode 340 may include one or more alloys containing a first metallic element and one or more second metallic elements. Each of the second metallic elements may be less or more reactive to the transition metal oxide in the switching oxide layer than the first metallic element. In some embodiments, the first metallic element may be Ta. The second metallic elements may include one or more of tungsten (W), hafnium (Hf), molybdenum (Mo), niobium (Nb), zirconium (Zr), etc. In some embodiments, the ratio of the first metallic element to the second metallic element(s) in an alloy in the second electrode 340 may be about 50 atomic percent. In some embodiments, the suitable ratio of the first metallic element to the second metallic element in the alloy may be optimized from the entire composition range. During a forming process, the second metallic element(s) may create fewer oxygen vacancies in the switching oxide layer than the first metallic element. As such, the lateral size of the filament formed in an RRAM device comprising a second electrode containing the alloy may be smaller than that of the filament formed in an RRAM device comprising a second electrode made of only the first metal.

In some implementations, second electrode 340 may include multiple layers of different metallic materials. For example, second electrode 340 may include a layer of titanium (Ti) and a layer of tantalum (Ta). The layer of Ti may be much thinner than the layer of Ta. For example, a thickness of the layer of Ti may be between about 0.2 nm and 5 nm. A thickness of the layer of Ta may be about 50 nm. In some embodiments, the thickness of the layer of Ti may be between 0.3 nm and 2 nm. Both Ti and Ta may trap and release oxygen during device operations. The incorporation of the thin Ti layer into the RRAM device may change the virgin resistance of the RRAM device, result in a less abrupt forming process, reduce the forming voltage, reduce the reset current, and reduce voltage and/or current requirements in subsequent operation processes.

FIG. 4 illustrates a cross-sectional view of an example compound non-reactive electrode 400 in accordance with another implementation of the present disclosure.

As shown, non-reactive electrode 400 may include a metal nitride layer 410 and a metal layer 420. Metal layer 420 may be fabricated on metal nitride layer 410. Metal nitride layer 410 may include one or more layers of one or more metal nitrides. Examples of the metal nitrides may include TiN, TaN, etc. Metal layer 420 may include one or more noble metals (e.g., Pt, Pb, Ru, etc.). In some embodiments, metal layer 420 may be thinner than metal nitride layer 410. In some embodiments, the thickness of metal nitride layer 410 may be between about 20 nm and about 25 nm. In some embodiments, the thickness of metal nitride layer 410 may be between about 20 nm and about 50 nm. In some embodiments, the thickness of metal nitride layer 410 may be between about 20 nm and about 30 nm. The thickness of metal layer 420 may be between about 3 nm and about 10 nm. In some embodiments, metal layer 420 is thicker than 2-3 nm and may include a continuous film of the noble metal(s) that cover metal nitride layer 410.

FIG. 5 illustrates a cross-sectional view of an example RRAM device 500 including a compound non-reactive electrode in accordance with one implementation of the present disclosure.

RRAM device 500 may include an adhesive layer 510, a first electrode 520, a switching oxide layer 530, an interface layer A (ILA) 550, and a second electrode 540. First electrode 520, switching oxide layer 530, and second electrode 540 may be the same as first electrode 320, switching oxide layer 330, and second electrode 340 as described in connection with FIG. 3A, respectively. As shown, first electrode 520 may include a metal nitride layer 410 and a metal layer 420 as described in connection with FIG. 4. In some embodiments, adhesive layer 510 may be regarded as being part of first electrode 520.

Adhesive layer 510 may include one or more suitable metallic materials that may enhance the adherence between the substrate and the components of RRAM device 500. In some embodiments, adhesive layer 510 may include one or more layers of Ti, Ta, etc.

ILA 550 (also referred to as the “first interface layer”) may include a first material that is more chemically stable than the transition metal oxide in the switching oxide layer. The first material may include, for example, Al₂O₃, MgO, Y₂O₃, La₂O₃, etc. ILA 550 may include a discontinuous film of the first material and/or a continuous film of the first material. In some embodiments, a thickness of ILA 550 may be between about 0.2 nm and about 0.5 nm. In some embodiments, the ILA 550 may include an Al₂O₃ film having a thickness equal to or less than 0.5 nm. In some embodiments, the ILA 550 may be and/or include an Al₂O₃ film having a thickness less than 1 nm. With ILA 550 including aluminum oxide, RRAM device 500 may be a high-resistance and annealing-resistant RRAM device.

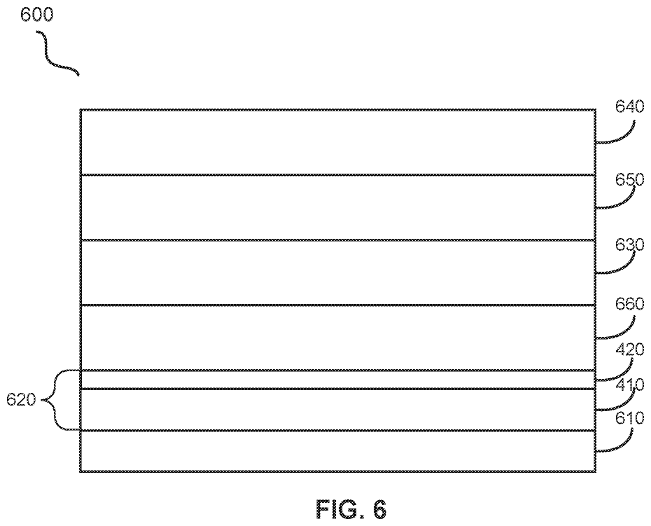

FIG. 6 illustrates a cross-sectional view of an example RRAM device 600 containing a compound non-reactive electrode in accordance with a further implementation of the present disclosure.

RRAM device 600 may include an adhesive layer 610, a first electrode 620, an interface layer B (ILB) 660, a switching oxide layer 630, an interface layer A (ILA) 650, and a second electrode 640. First electrode 620, switching oxide layer 630, and second electrode 640 may be the same as first electrode 320, switching oxide layer 330, and second electrode 340 as described in connection with FIG. 3A, respectively. Adhesive layer 610 may be the same as adhesive layer 510 of FIG. 5. ILA 650 may be the same as ILA 550 of FIG. 5. In some embodiments, RRAM device 600 may further include a substrate (not shown) as described in connection with FIG. 3A.

ILB 660 may include a second material that is more chemically stable than the transition metal oxide in switching oxide layer 630. The second material may include, for example, Al₂O₃, MgO, Y₂O₃, La₂O₃, etc. ILB 660 may include a discontinuous film of the second material and/or a continuous film of the second material. In some embodiments, a thickness of ILB 660 may be between about 0.2 nm and about 0.5 nm. In some embodiments, ILB 660 may include an Al₂O₃ film having a thickness equal to or less than 0.5 nm. In some embodiments, ILB 660 may be and/or include an Al₂O₃ film having a thickness less than 1 nm. With the first interface layer and the second interface layer, RRAM device 600 may be a high-resistance and annealing-resistant RRAM device.

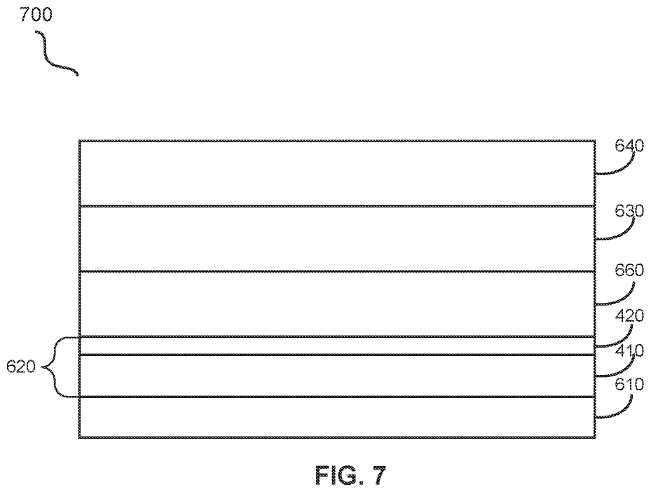

In some embodiments, ILA 650 may be omitted from RRAM 600. For example, as shown in FIG. 7, RRAM device 700 may include the adhesive layer 610, the first electrode 620, the interface layer B (ILB) 660, the switching oxide layer 630, and the second electrode 640 as described in connection with FIG. 6.

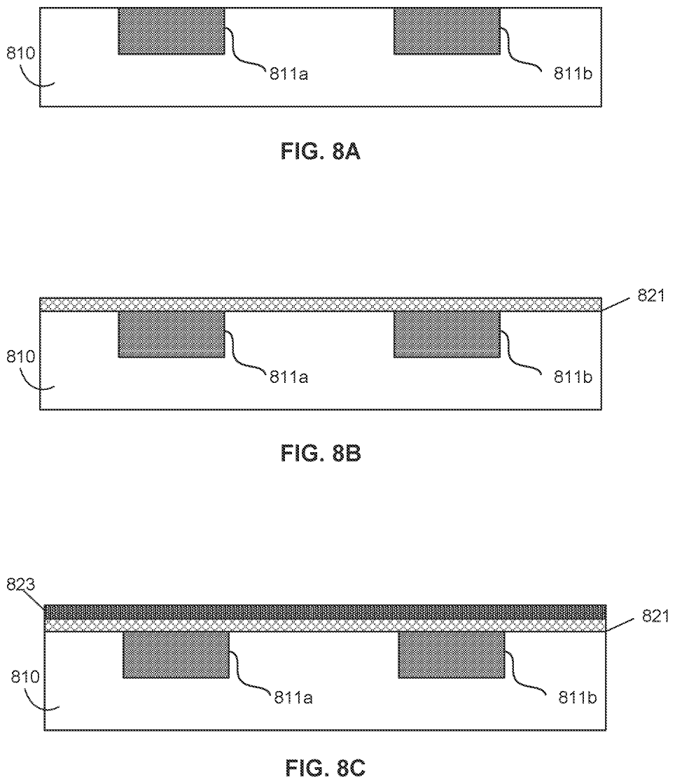

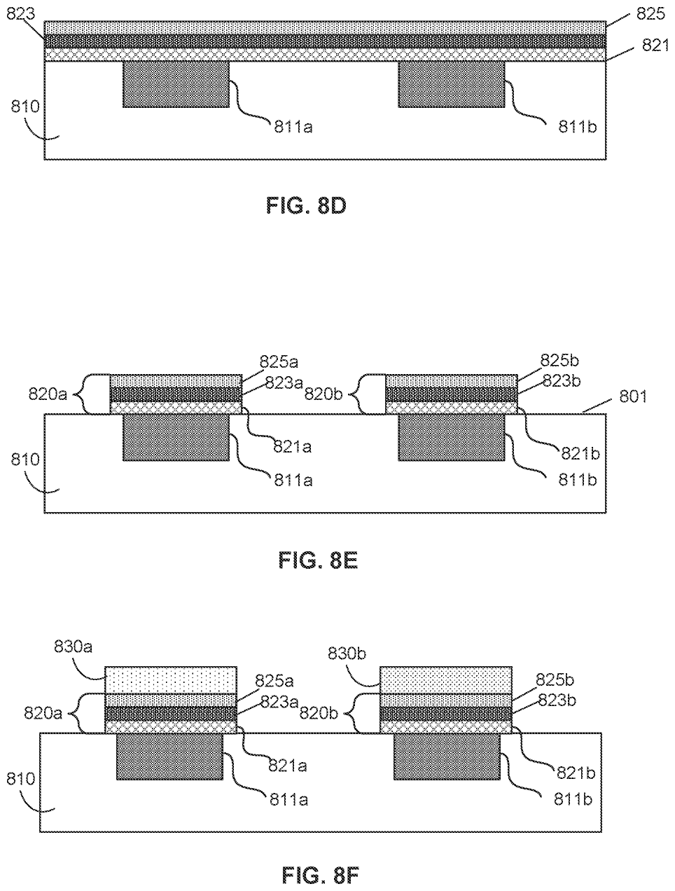

FIGS. 8A, 8B, 8C, 8D, 8E, and 8F are schematic diagrams illustrating cross-sectional views of structures for fabricating non-reactive electrodes of RRAM devices in accordance with some embodiments of the present disclosure.

As shown in FIG. 8A, a substrate 810 may be provided. Substrate 810 may include one or more layers of any suitable material that may serve as a substrate for fabricating an RRAM device, such as silicon (Si), silicon dioxide (SiO₂), silicon nitride (Si₃N₄), aluminum oxide (Al₂O₃), aluminum nitride (AlN), etc. In some embodiments, substrate 810 may include diodes, transistors, interconnects, integrated circuits, etc. Substrate 810 may include a driving circuit including one or more electrical circuits (e.g., an array of electrical circuits) that may be individually controllable. In some embodiments, the driving circuit may include one or more complementary metal-oxide-semiconductor (CMOS) drivers. In some embodiments, substrate 810 may include one or more dielectric layers, interconnect layers, transistors, and/or any other suitable component (not shown) for fabricating a crossbar circuit. Each of the interconnect layers may include one or more metallic pads and/or metallic vias and may provide electrical connectivity between devices fabricated on substrate 810.

As illustrated in FIG. 8A, substrate 810 may include an interconnect layer including one or more metallic interconnects (e.g., metallic pads and/or metallic vias). For example, a first interconnect layer may include metallic interconnects 811a and 811b (also referred to as the “first metallic interconnect” and the “second metallic interconnect”). In some embodiments, metallic interconnects 811a and 811b may be metallic pads containing Tungsten (W), Al, Cu, and any other suitable metal. In some embodiments, metallic interconnects 811a and 811b may be metallic vias containing aluminum (Al), copper (Cu), tungsten (W), etc. Each of metallic interconnects 811a and 811b may be connected to another device (not shown), such as a transistor, a diode, etc. In some embodiments, metallic interconnects 811a-b may include tungsten (W) vias and doped polycrystalline Si (poly-Si) terminals where poly-Si terminals may connect transistor or diode terminals (not shown).

As shown in FIG. 8B, an adhesive layer 821 may be fabricated on metallic interconnects 811a and 811b, and substrate 810. Adhesive layer 821 may include a layer of Ta, Ti, and/or any other suitable material that may enhance the adhesion between substrate 810 and the components of the RRAM devices to be fabricated on substrate 810.

As shown in FIG. 8C, a metal nitride layer 823 may be fabricated on adhesive layer 821. Metal nitride layer 823 may include one or more layers of one or more metal nitrides that are electronically conductive and nonreactive to the switching oxide of the RRAM devices to be fabricated on substrate 810. The metal nitrides may include, for example, TiN, TaN, etc.

As shown in FIG. 8D, a metal layer 825 may be fabricated on metal nitride layer 823. Metal layer 825 may include one or more layers of one or more suitable metals (also referred to as the “nonreactive metals”) that are electronically conductive and nonreactive to the switching oxide of the RRAM devices to be fabricated on substrate 810. Examples of the nonreactive materials may include Pt, Pd, Ir, Ru, etc.

One or more portions of adhesive layer 821, metal nitride layer 823, and metal layer 825 may be selectively removed to fabricate one or more bottom electrodes. For example, as shown in FIG. 8E, a first bottom electrode 820a and a second bottom electrode 820b may be fabricated on metallic interconnect 811a and metallic interconnect 811b, respectively, by patterning and etching adhesive layer 821, metal nitride layer 823, and metal layer 825. First bottom electrode 820a may include a first adhesive layer 821a, a first metal nitride layer 823a, and a first metal layer 825a. Second bottom electrode 820b may include a second adhesive layer 821b, a second metal nitride layer 823b, and a second metal layer 825b. First adhesive layers 821a and 821b may correspond to the etched adhesive layer 821. First metal nitride layer 823a and second metal nitride layer 823b may correspond to the etched metal nitride layer 823. First metal layer 825a and second metal layer 825b may correspond to the etched metal layer 825. The lateral dimension of bottom electrode 820a-b may be greater than that of metallic interconnect 811a-b in some embodiments. First bottom electrode 820a may directly contact metallic interconnect 811a to form an ohmic contact. Second bottom electrode 820b may directly contact second metallic interconnect 811b to form an ohmic contact. First bottom electrode 820a and second bottom electrode 820b may further contact one or more portions of substrate 810, such as one or more portions of a surface 801 of the substrate 810 (e.g., the top surface of the substrate 810).

As shown in FIG. 8F, an RRAM stack 830a and an RRAM stack 830b may be fabricated on first bottom electrode 820a and second bottom electrode 820b, respectively. Each of RRAM stacks 830a and 830b may include a switching oxide layer, a top electrode, and one or more interface layers as described in connection with FIGS. 3A-7 above. In some embodiments, RRAM stacks 830a and 830b may be fabricated utilizing technologies described in U.S. patent application Ser. Nos. 17/654,476 and 17/936,830, which are incorporated herein by reference.

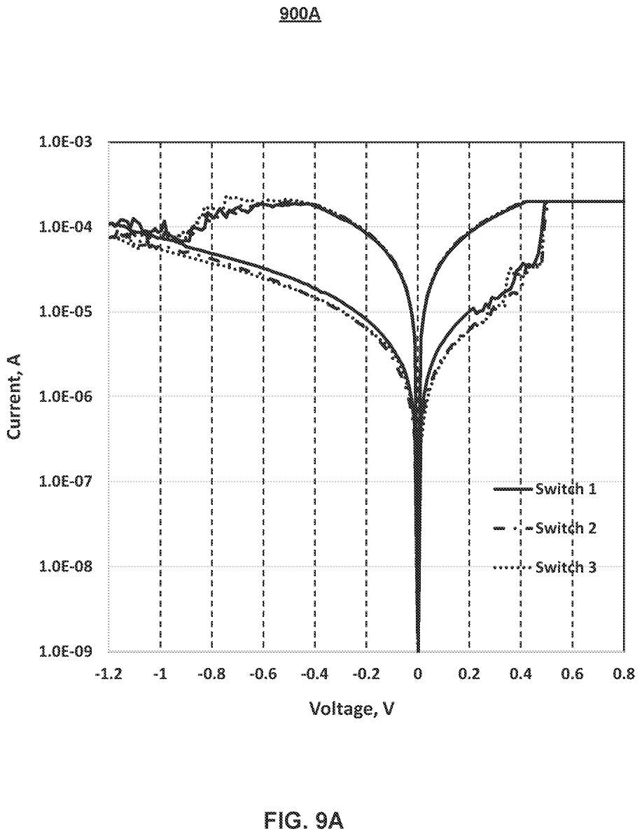

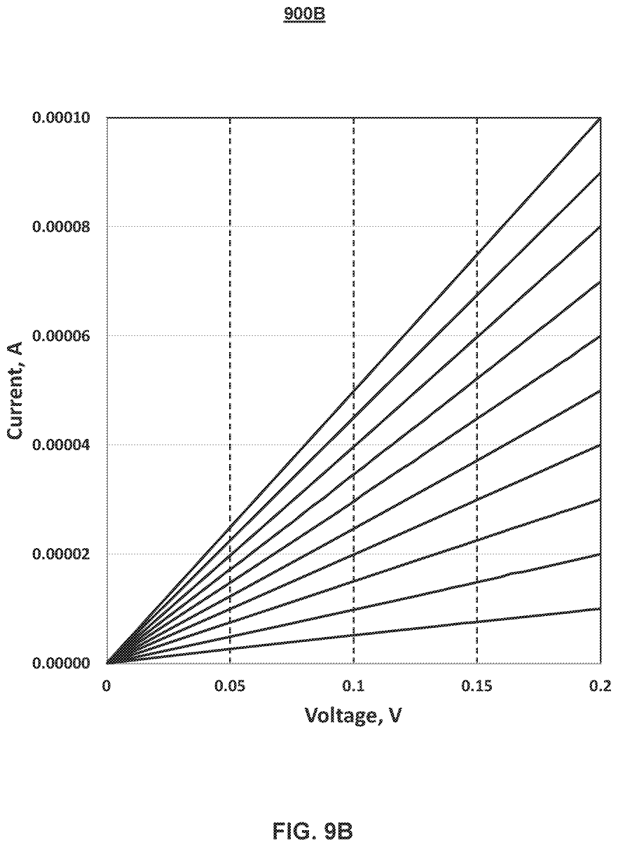

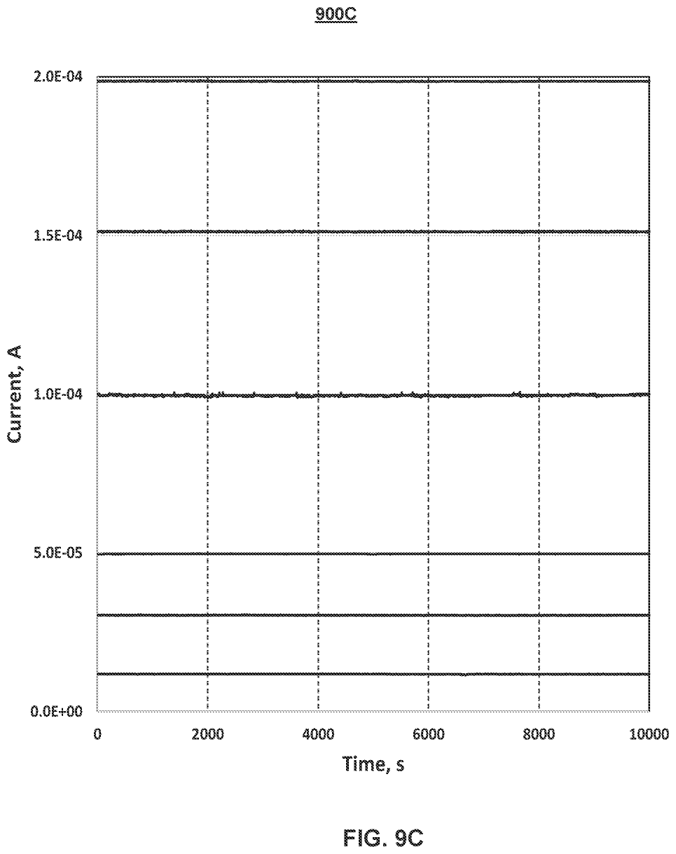

FIG. 9A is a diagram 900A showing I-V (current-voltage) characteristics of an example RRAM device including a compound non-reactive electrode in accordance with some embodiments of the present disclosure. FIG. 9B illustrates an I-V curve 900B showing the analog behavior of the RRAM device. FIG. 9C is a diagram 900C illustrating device read current characteristics of the example RRAM device over time.

As shown in FIG. 9A, the RRAM device presents repeatable and desirable set-reset operations for multiple switches (e.g., switch 1, switch 2, and switch 3), demonstrating stabilities for multiple switch behavior. As shown in FIG. 9B, the RRAM device presents desirable analog behavior. That is, the device resistance can be tuned to multi-levels (or analog behavior) by controlling the current compliance, and the current is linearly proportional to the voltage (or linearity behavior) at each resistance state. As shown in FIG. 9C, diagram 900C may represent results of a device retention test for the RRAM device's capabilities to retain the resistance levels with time and the results of a read stability test as the RRAM device is under constant reading (with a reading voltage of 0.2V) for its capabilities to retain the resistance levels with time. As shown in FIG. 9C, the RRAM device exhibit desirable device read stability over time.

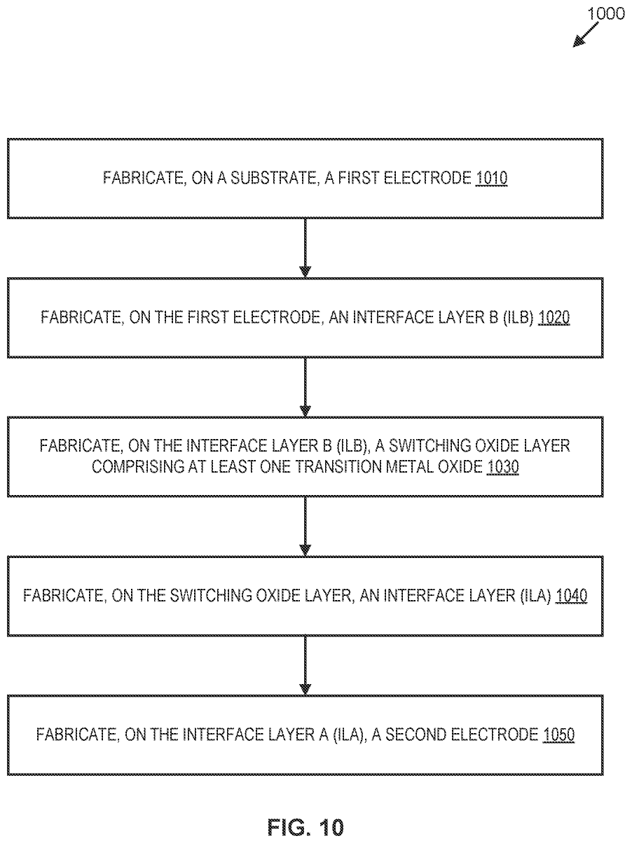

FIG. 10 is a flow diagram illustrating an example 1000 of a method for fabricating an RRAM device according to some embodiments of the disclosure, including RRAM devices 500, 600, and 700 of FIGS. 5, 6, and 7.

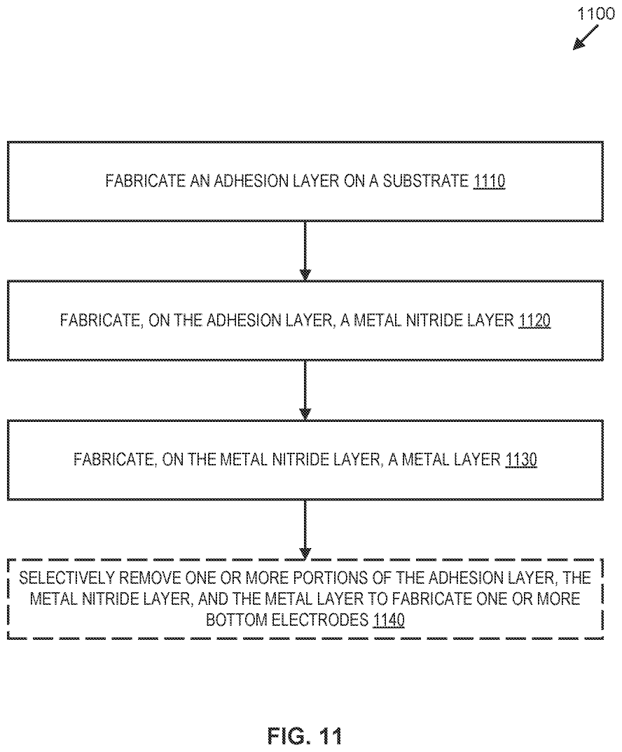

At block 1010, a first electrode may be fabricated on a substrate. Fabricating the first electrode may involve depositing one or more layers of a metal nitride, such as TiN or TaN. For example, fabricating the first electrode may involve depositing one or more layers of TiN, utilizing an atomic layer deposition (ALD) technique, a physical vapor deposition (PVD) technique, a reactive sputtering of Ti technique, and/or any other suitable deposition technique. Fabricating the first electrode may further include depositing one or more non-reactive metals on the metal nitride. The first electrode may be and/or include a compound non-reactive electrode as described in connection with FIG. 4 above. In some embodiments, fabricating the first bottom electrode may involve performing one or more operations as described in conjunction with FIG. 11 below.

At block 1020, an interface layer B (ILB) may be fabricated on the first electrode. The ILB may include a material that is more chemically stable than the transition metal oxide(s) of the switching oxide layer (such as AlOₓ, like Al₂O₃) described subsequently. For example, fabricating the interface layer B may involve depositing AlOₓ, utilizing an atomic layer deposition (ALD) technique, a physical vapor deposition (PVD) technique, a reactive sputtering of Al technique, and/or any other suitable deposition technique. The interface layer B may be and/or include ILB 660 as described in connection with FIG. 6 above. In some embodiments, block 1020 may be omitted from method 1000.

At block 1030, a switching oxide layer comprising one or more transition metal oxides may be fabricated on the interface layer B. The transition metal oxides may include, e.g., HfOₓ. For example, fabricating the switching oxide layer may involve depositing HfOₓ, utilizing an atomic layer deposition (ALD) technique, a physical vapor deposition (PVD) technique, a reactive sputtering of Hf technique, and/or any other suitable deposition technique. The switching oxide layer may be and/or include switching oxide layer 630 as described in connection with FIG. 6 above.

At block 1040, an interface layer A (ILA) may be fabricated on the switching oxide layer. The ILA may include a material that is more chemically stable than the transition metal oxide(s) of the switching oxide layer, such as AlOₓ, like Al₂O₃. For example, fabricating the interface layer A may involve depositing AlOₓ, utilizing an atomic layer deposition (ALD) technique, a physical vapor deposition (PVD) technique, a reactive sputtering of Al technique, and/or any other suitable deposition technique. The interface layer A may be and/or include ILA 650 as described in connection with FIG. 6 above.

At block 1050, a second electrode may be fabricated on the interface layer A. Fabricating the second electrode may involve fabricating one or more layers of one or more metallic materials that are electronically conductive and reactive to the switching oxide. For example, fabricating the second electrode may involve depositing one or more layers of Ta, utilizing a physical vapor deposition (PVD) technique, and/or any other suitable deposition technique. The second electrode may be and/or include second electrode 640 as described in connection with FIG. 6 above.

FIG. 11 is a flow diagram illustrating an example 1100 of a method for fabricating a non-reactive electrode according to some embodiments of the disclosure, such as the non-reactive electrodes as described in conjunction with FIGS. 4 and 8A-8F.

At block 1110, an adhesive layer may be fabricated on a substrate. Fabricating the adhesive layer may involve depositing a layer of a metal that may enhance the adhesion between the substrate and the bottom electrode and/or the other components of the RRAM device to be fabricated on the substrate, such as Ta, Ti, etc. In some embodiments, fabricating the adhesive layer may involve depositing a Ti film or a Ta film with a thickness between about 2 nm and 5 nm. The adhesive layer may be deposited using suitable PVD techniques and/or any other suitable deposition techniques for depositing the metals. In some embodiments, block 1110 may be omitted from method 1100.

At block 1120, a metal nitride layer may be fabricated on the adhesive layer. Fabricating the metal nitride layer may involve depositing a layer of a metal nitride that is not reactive to the transition metal oxide in the switching oxide layer to be fabricated on the bottom electrode. For example, fabricating the metal nitride layer may include depositing a layer of TiN, TaN, etc. utilizing ALD, PVD, reactive sputtering techniques or any other suitable deposition techniques.

At block 1130, a metal layer may be fabricated on the metal nitride layer. Fabricating the metal layer may involve depositing one or more nonreactive metals as described herein. In some embodiments, fabricating the metal layer may include depositing Pt, Pd, Ir, Ru, etc. on the metal nitride layer utilizing PVD techniques or any other suitable deposition techniques. In some embodiments, fabricating the metal layer may involve depositing a layer of Pt, Pd, Ir, Ru with a thickness between about 3 nm and about 10 nm.

In some embodiments, one or more portions of the adhesive layer, the metal nitride layer, and the metal layer may be selectively removed to fabricate one or more bottom electrodes at block 1140. For example, the adhesive layer, the metal nitride layer, and the metal layer may be patterned and etched to fabricate a first bottom electrode 820a and a second bottom electrode 820b as described in connection with FIG. 8E.

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” as used herein may mean within a range of normal tolerance in the art, such as within 2 standard deviations of the mean, within ±20% of a target dimension in some embodiments, within ±10% of a target dimension in some embodiments, within ±5% of a target dimension in some embodiments, within ±2% of a target dimension in some embodiments, within ±1% of a target dimension in some embodiments, and yet within ±0.1% of a target dimension in some embodiments. The terms “approximately” and “about” may include the target dimension. Unless specifically stated or obvious from context, all numerical values described herein are modified by the term “about.”

As used herein, a range includes all the values within the range. For example, a range of 1 to 10 may include any number, combination of numbers, sub-range from the numbers of 1, 2, 3, 4, 5, 6, 7, 8, 9, and 10 and fractions thereof.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. A resistive random-access memory (RRAM) device, comprising:
a first electrode comprising:
a metal nitride layer comprising a metal nitride; and
a metal layer fabricated on the metal nitride layer;
a second electrode comprising a conductive material; and
a switching oxide layer positioned between the first electrode and the second electrode, wherein the switching oxide layer comprises at least one transition metal oxide, wherein the metal layer comprises a metal that is not reactive to the at least one transition metal oxide.

2. The RRAM device of claim 1, wherein the metal nitride comprises at least one of titanium nitride or tantalum nitride.

3. The RRAM device of claim 1, wherein the metal that is not reactive to the at least one transition metal oxide comprises at least one of platinum, palladium, iridium, or ruthenium.

4. The RRAM device of claim 3, wherein the metal layer is thinner than the metal nitride layer.

5. The RRAM device of claim 4, wherein a thickness of the metal layer is between 3 nm and 10 nm.

6. The RRAM device of claim 5, wherein a thickness of the metal nitride layer is between 20 nm and 50 nm.

7. The RRAM device of claim 1, wherein the at least one transition metal oxide comprises at least one of HfOₓ or TaO_{y}, wherein x≤2.0, and wherein y≤2.5.

8. The RRAM device of claim 1, wherein the conductive material in the second electrode comprises tantalum.

9. The RRAM device of claim 1, further comprising:
an interface layer positioned between the switching oxide layer and the second electrode, wherein the interface layer comprises aluminum oxide.

10. The RRAM device of claim 1, further comprising an adhesive layer comprising at least one of titanium or tantalum, wherein the metal nitride layer is fabricated on the adhesive layer.

11. A method for fabricating a resistive random-access memory (RRAM) device, comprising:
fabricating a first electrode, wherein the first electrode comprises:
a metal nitride layer comprising a metal nitride; and
a metal layer fabricated on the metal nitride layer;
fabricating a switching oxide layer on the first electrode, wherein the switching oxide layer comprises at least one transition metal oxide, wherein the metal layer comprises a metal that is not reactive to the at least one transition metal oxide; and
fabricating, on the switching oxide layer, a second electrode comprising a conductive material.

12. The method of claim 11, wherein the metal nitride comprises at least one of titanium nitride or tantalum nitride.

13. The method of claim 12, wherein the metal that is not reactive to the at least one transition metal oxide comprises at least one of platinum, palladium, iridium, or ruthenium.

14. The method of claim 13, wherein the metal layer is thinner than the metal nitride layer.

15. The method of claim 14, wherein a thickness of the metal layer is between 3 nm and nm.

16. The method of claim 15, wherein a thickness of the metal nitride layer is between nm and 50 nm.

17. The method of claim 11, wherein the at least one transition metal oxide comprises at least one of HfOₓ or TaO_{y}, wherein x≤2.0, and wherein y≤2.5.

18. The method of claim 11, further comprising:
fabricating an interface layer on the switching oxide layer, wherein the interface layer is positioned between the switching oxide layer and the second electrode, and wherein the interface layer comprises aluminum oxide.

19. The method of claim 11, further comprising fabricating an adhesive layer comprising at least one of titanium or tantalum, wherein the metal nitride layer is fabricated on the adhesive layer.

20. A method for fabricating a non-reactive electrode, comprising:
fabricating an adhesive layer comprising at least one of titanium or tantalum;
fabricating, on the adhesive layer, a metal nitride layer comprising at least one metal nitride, wherein the metal nitride comprises at least one of titanium nitride or tantalum nitride;
fabricating, on the metal nitride layer, a metal layer comprises a noble metal; and
selectively removing one or more portions of the adhesive layer, the metal nitride layer, and the metal layer to fabricate the non-reactive electrode.
